(19) United States
(12) Patent Application Publication
(10) Pub. No.: US 2014/0307398 A1
(43) Pub. Date: Oct. 16, 2014

(54) IMAGE DISPLAY DEVICE

(71) Applicant: SUMITOMO BAKELITE COMPANY LIMITED, Shinagawa-ku, Tokyo (JP)

(72) Inventors: Toshimasa Eguchi, Tokyo (JP); Toshiaki Chuma, Tokyo (JP); Manabu Naito, Tokyo (JP)

(73) Assignee: SUMITOMO BAKELITE COMPANY LIMITED, Shinagawa-ku, Tokyo (JP)

(21) Appl. No.: 14/361,831

(22) PCT Filed: Nov. 29, 2012
(86) PCT No.: PCT/JP2012/080979

§ 371 Date: May 30, 2014

(30) Foreign Application Priority Data
Dec. 1, 2011 (JP) 2011-263864
Jan. 19, 2012 (JP) 2012-009274
Jan. 19, 2012 (JP) 2012-009275
Jan. 19, 2012 (JP) 2012-009276

(51) Int. Cl. H05K 1/03; H05K 1/02

(52) U.S. Cl. CPC H05K 1/0393; H05K 1/0274
USPC 361/749

(57) ABSTRACT

An image display device includes: a plate-like base substrate (22), a transparent opposite substrate (3) provided opposite to the base substrate (22) and having flexibility, and a display element provided between the base substrate (22) and the opposite substrate (3), the display element including a transparent element substrate (41) having flexibility and a working unit (43) provided on a side of one surface of the element substrate (41), wherein each of the opposite substrate (3) and the element substrate (41) contains a resin material or a plate-like glass base member, and wherein in the case where the opposite substrate (3) contains the glass base member, an average thickness of the opposite substrate (3) is in the range of 0.02 to 0.2 mm, and in the case where the element substrate (41) contains the glass base member, an average thickness of the element substrate (41) is in the range of 0.02 to 0.2 mm. This makes it possible to provide an image display device having light weight and excellent impact resistance.

### TECHNICAL FIELD

The present invention relates to an image display device.

### RELATED ART

Recently, portable image display devices, in which users can view images and the like in a state that they hold them, are being marketed. Such an image display device includes an image display unit capable of electrooptically displaying an image and changing its displayed content depending on the operation of the user. Therefore, it can display various kinds of information according to the intention of the user. Further, since such an image display device has portability, it can be used not only indoors, but also used outdoors by being taken out. Therefore, the use form thereof is expanding rapidly. Moreover, there are also image display devices capable of displaying information transmitted from outside by being equipped with communication facilities.

For example, Patent document 1 discloses a mobile display terminal in which an input unit such as a touch panel and an output unit such as a liquid crystal display are incorporated into a single device. Since an external shape of such a display terminal is a thin panel shape, it can be easily held and also has excellent portability. However, an inner structure of the display terminal cannot always have excellent portability. This reason is as follows. Since the input unit such as the touch panel or the output unit such as the liquid crystal display has heavy weight, it is unsuitable for being held for a long period of time even if having portability. Further, since the output unit has especial weakness against impact, it exhibits poor durability against drop impact.

### PRIOR ART DOCUMENT

### Patent Document

Patent document 1: JP-A 2008-269525

### SUMMARY OF THE INVENTION

### Problem to be Solved by the Invention

It is an object of the present invention to provide an image display device having light weight and excellent impact resistance.

### Means for Solving Problem

In order to achieve the object described above, the present invention includes the following features (1) to (17).

(1) An image display device comprising:

a plate-like base substrate;

a transparent opposite substrate provided opposite to the base substrate and having flexibility; and

a display element provided between the base substrate and the opposite substrate, the display element including a transparent element substrate having flexibility and a working unit provided on a side of one surface of the element substrate,

wherein each of the opposite substrate and the element substrate contains a resin material or a plate-like glass base member, and

wherein in the case where the opposite substrate contains the glass base member, an average thickness of the opposite substrate is in the range of 0.02 to 0.2 mm, and in the case where the element substrate contains the glass base member, an average thickness of the element substrate is in the range of 0.02 to 0.2 mm.

(2) The image display device according to the above feature (1), wherein bending rigidity of the element substrate is lower than that of the opposite substrate.

(3) The image display device according to the above feature (1), wherein in the case where the opposite substrate contains the resin material, the opposite substrate is formed by impregnating the resin material into a glass fabric, and in the case where the element substrate contains the resin material, the element substrate is formed by impregnating the resin material into a glass fabric.

(4) The image display device according to the above feature (1), wherein the glass base member is formed of alkali-free glass.

(5) The image display device according to the above feature (1), wherein in the case where the opposite substrate contains the glass base member, the opposite substrate contains the glass base member and a resin layer laminated on the glass base member, and in the case where the element substrate contains the glass base member, the element substrate contains the glass base member and a resin layer laminated on the glass base member.

(6) The image display device according to the above feature (1), wherein the display element further includes an opposite element substrate provided opposite to the element substrate via the working unit.

(7) The image display device according to the above feature (1), wherein the working unit is capable of electrooptically displaying an image.

(8) The image display device according to the above feature (1), comprising a capacitance-type touch panel input unit.

(9) The image display device according to the above feature (1), wherein the opposite substrate contains the resin material.

(10) The image display device according to the above feature (9), wherein an average thickness of the opposite substrate is in the range of 0.02 to 0.8 mm.

(11) The image display device according to the above feature (9), wherein the resin material contained in the opposite substrate contains a polycarbonate-based resin or a (meth)acrylate-based resin as a major component thereof.

(12) The image display device according to the above feature (1), wherein the opposite substrate contains the glass base member.

(13) The image display device according to the above feature (1), wherein the element substrate contains the resin material.

(14) The image display device according to the above feature (13), wherein an average thickness of the element substrate is in the range of 0.01 to 0.3 mm.

(15) The image display device according to the above feature (13), wherein the resin material contained in the element substrate contains a cross-linked product of a cross-linkable resin as a major component thereof.

(16) The image display device according to the above feature (15), wherein the cross-linkable resin is an alicyclic epoxy-based resin or an alicyclic acryl-based resin.

(17) The image display device according to the above feature (1), wherein the element substrate contains the glass base member.

### Effect of the Invention

According to the present invention, by constituting both an opposite substrate and an element substrate so as to contain a resin material or a plate-like glass base member and have flexibility, it is possible to obtain an image display device having light weight, excellent impact resistance and good portability.

### BRIEF DESCRIPTION OF THE DRAWINGS

FIG. 1 is a sectional view (frame format) showing an embodiment of an image display device of the present invention.

FIG. 2 is an exploded perspective view showing an embodiment of the image display device of the present invention.

### MODE FOR CARRYING OUT THE INVENTION

Hereinafter, an image display device of the present invention will be described in detail based on preferred embodiments shown in the accompanying drawings.

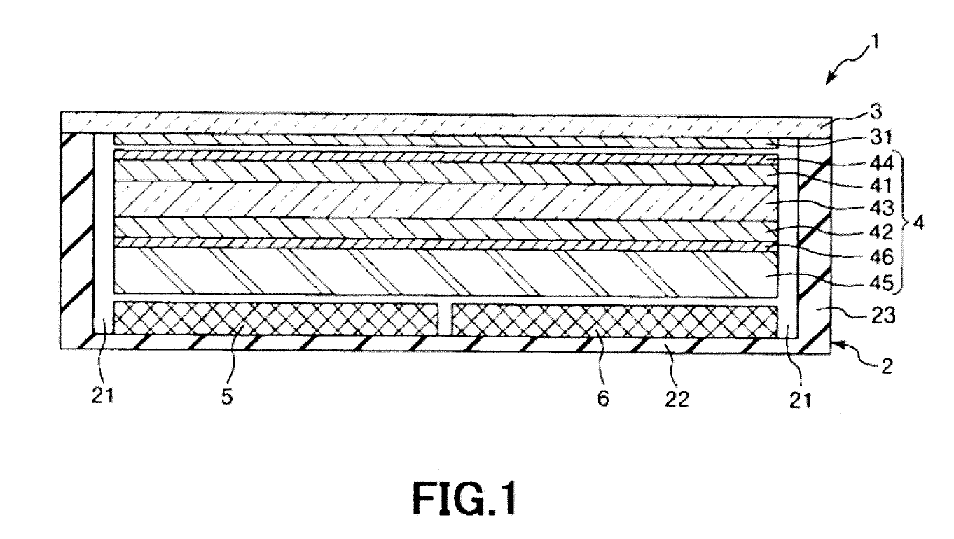

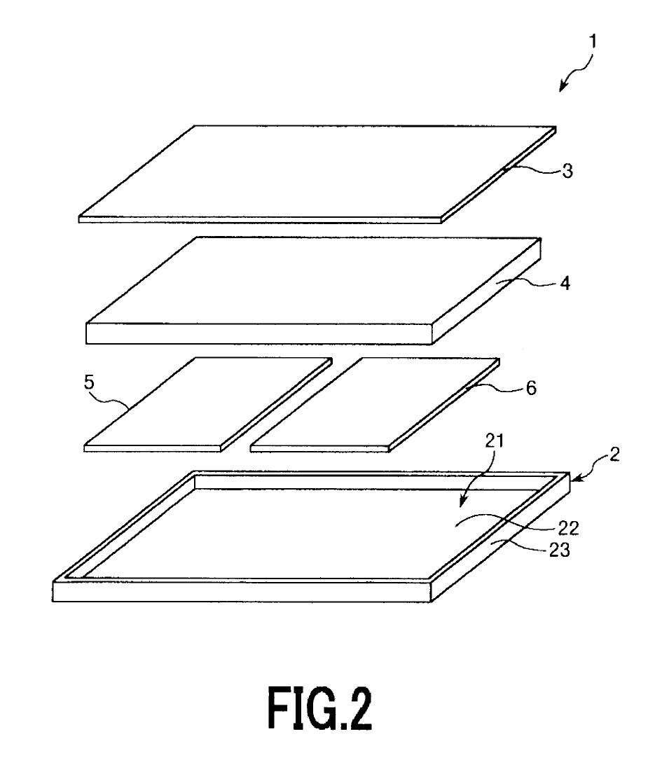

FIG. 1 is a sectional view (frame format) showing an embodiment of the image display device of the present invention and FIG. 2 is an exploded perspective view showing an embodiment of the image display device of the present invention. In this regard, in the following description, the upper side in each of FIGS. 1 and 2 will be referred to as “upper” and the lower side thereof will be referred to as “lower”.

### First Embodiment

An image display device shown in FIGS. 1 and 2 is of a plate-like whole shape, and includes a housing 2 having a storage portion 21, a lid body 3 fixed to the housing 2 so as to cover the storage portion 21, a display element 4 stored in the storage portion 21, a battery 5 which is a drive power of the display element 4 and a control unit 6 which controls the drive of the display element 4.

Among them, the lid body 3 is formed from a transparent plate. Therefore, a user of the image display device 1 can visually observe an image displayed on the display element 4 through the lid body 3. That is, an upper surface of the lid body 3 constitutes a display surface of the image display device 1.

Further, the display element 4 includes a first transparent substrate 41, a second transparent substrate 42 and a working unit 43 provided therebetween. Therefore, a light (image) emitted from or adjusted in the working unit 43 can be visually observed through the first substrate 41 and the lid body 3.

In this embodiment, each of the first substrate and the lid body 3 contains a resin material. Therefore, since the first substrate 41 and the lid body 3 have very light weight as compared with a case where they are constituted from a thick glass substrate, it is possible to reduce weight of the image display device 1.

Further, each of the first substrate 41 and the lid body 3 has flexibility. Therefore, the first substrate 41 and the lid body 3 have excellent durability against deformation such as bend and high impact resistance. As a result, the first substrate 41 and the lid body 3 can mitigate stress concentration with respect to the display element 4 and the like, to thereby prevent the working unit 43 of the display element 4 from being destroyed when the image display device 1 is dropped.

Hereinafter, description will be made on a configuration of each part of the image display device 1 in detail.

(Housing)

The housing 2 includes a bottom portion (plate-like base substrate) 22 being of a substantially rectangle shape in a planar view thereof and a peripheral portion 23 erected along four sides of the bottom portion 22, and they are integrally formed with each other. By such a configuration, the housing 2 has the storage portion 21 which is a space surrounded by the bottom portion 22 and the peripheral portion 23.

Examples of a constituent material of the housing 2 include, but are not especially limited to, a metal material such as aluminum, magnesium or titanium, an alloy material containing them, a resin material such as a polycarbonate-based resin or ABS resin, a composite material containing them, and the like. By constituting the housing 2 from these materials, it is possible to reduce weight of the housing 2 (image display device 1).

Further, the housing 2 may have flexibility. In the case where the housing 2 has the flexibility, since it can be also imparted to the entirety of the image display device 1 including the lid body 3 and the display element 4, it is possible to use the image display device 1 while bending the entirety thereof. Furthermore, since the stress concentration with respect to the display element 4 is further mitigated, it is possible to improve bend resistance and impact resistance of the display element 4 (image display device 1).

In this regard, the flexibility means a property that although the housing 2 can be easily bent when, for example, seeking to bend the housing 2 with hand, the housing 2 does not bend due to weight thereof. Further, the bend resistance means a property that when the housing 2 is bent with hand and then released, the housing 2 is restored at an original shape thereof, and the impact resistance means a property that when the housing 2 is dropped, the housing 2 is not chipped off or crashed.

(Display Element)

The display element 4 is an element which is stored in the storage portion 21 and displays an image. The image includes, for example, a still image such as a character, a pattern or a photograph, a moving image and the like.

As described above, the display element 4 shown in FIG. 1 includes the first substrate (element substrate) 41 and the second substrate (opposite element substrate) 42 which are provided opposite to each other, and the working unit 43 provided therebetween. An electrical circuit (not shown) for operating (driving) the working unit 43 is provided on a surface of any one of the first substrate 41 and the second substrate 42 positioned on a side of the working unit 43. This electrical circuit (TFT circuit) contains pixel electrodes, transistors, electrical wirings and the like. In this regard, since the image displayed by the working unit 43 is visually observed from a side of the lid body 3 in this embodiment, the electrical circuit is preferably provided on a side of the second substrate 42.

Further, although examples of the working unit include display units mechanically, chemically or electrooptically displaying an image, it is especially preferable to use the display unit electrooptically displaying the image (hereinafter, referred to as “electrooptic display unit”) such as a liquid crystal unit or an organic EL unit as the working unit 43. Such a working unit (electrooptic display unit) 43 can display a fine image capable of being switched at a high-speed.

In this regard, the “electrooptic display unit” means a display unit displaying an image by electrically controlling local luminous energies. Examples of the electrooptic display unit include a liquid crystal display element (LCD), an organic EL display element (OLED), an electrophoresis display element (electronic paper), a plasma display (PDP), a field emission display (FED) and the like. In this specification, description will be made on a case where the display element 4 is the liquid crystal display element, that is, a case where the working unit 43 is constituted from the liquid crystal display unit as one example.

Further, depending on the kind of the display element 4, any one of the first substrate 41 and the second substrate 42 may be omitted. Examples of such an element include the organic EL display element and the like. In this regard, in the case where the second substrate 42 is omitted, the electrical circuit for operating the working unit 43 is provided on a side of the first substrate 41.

The display element 4 shown in FIG. 1 includes a first polarizing plate 44 provided at an uppermost part, a backlight 45 provided at a lowermost part and a second polarizing plate 46 provided between the backlight 45 and the second substrate 42 in addition to the first substrate 41, the second substrate 42 and the working unit 43. Furthermore, the display element 4 may include a color filter substrate, a diffuser plate and the like each not shown.

As described above, the first substrate 41 has the transparency and the flexibility. Therefore, the first substrate 41 can mitigate the stress concentration with respect to the display element 4, to thereby improve the bend resistance and the impact resistance of the entirety of the image display device 1.

Further, the first substrate 41 contains a resin material. The first substrate 41 containing the resin material has excellent flexibility and becomes light weight. By reducing the weight of the first substrate 41, weight of the image display device 1 is also reduced. As a result, the image display device 1 can exhibit excellent portability suitable for being held for a long period of time.

Further, by reducing the weight of the image display device 1, it is also possible to weaken impact which would be applied to the image display device 1 when it is dropped from a high altitude. This makes it possible to decrease impact strength to the display element 4 due to the drop, to thereby prevent the working unit 43 from being destroyed.

In this regard, since such a first substrate 41 is difficult to be crashed unlike a thick glass substrate, the first substrate 41 can be safely used even if it is made so as to have a sufficiently thin thickness. By using such a thin first substrate 41, it is possible to reduce the weight of the first substrate 41 and to improve the transparency thereof.

A resin material contained in the first substrate 41 is not especially limited to a specific kind as long as it is a transparent material. Examples of such a resin material include a (meth)acrylate-based resin, an epoxy-based resin, a polystyrene-based resin, a polycarbonate-based resin, AS resin, a soft polyvinyl chloride-based resin, a polyamide-based resin, a polyimide-based resin and the like. One kind of these transparent materials or a mixture containing two or more kinds of them is used. Among them, a resin material containing a cross-linked product (cured product) of a cross-linkable resin as a major component thereof is preferably used for the first substrate 41. Since the cross-linkable resin is three-dimensionally cross-linked in the first substrate 41 containing the cross-linked product of the cross-linkable resin, the first substrate 41 has excellent flexibility and relatively high strength. Therefore, it is possible to make the first substrate 41 thinner. This makes it possible to obtain a first substrate 41 having transparency, bend resistance and impact resistance in an especially superior degree, and very light weight.

Further, the cross-linkable resin is not limited to a specific kind, but is preferably an alicyclic epoxy-based resin or an alicyclic acryl-based resin. A first substrate 41 containing a cross-linked product of these resins has especially excellent transparency and especially superior bend resistance and impact resistance.

Among them, as the alicyclic epoxy-based resin, an alicyclic epoxy-based resin having an alicyclic epoxy group is preferably used. Specifically, a resin material containing various kinds of cyclic epoxy resins such as an alicyclic polyfunctional epoxy resin, an alicyclic epoxy resin having a hydrogenated biphenyl skeleton and an alicyclic epoxy resin having a hydrogenated bisphenol A skeleton as a major component thereof is preferably used.

Concrete examples of such an alicyclic epoxy resin include 3,4-epoxycyclohexyl methyl-3′,4′-epoxycyclohexanecarboxylate, 3,4-epoxy-6-methyl cyclohexyl methyl-3,4-epoxy-6-methyl cyclohexanecarboxylate, 2-(3,4-epoxy)cyclohexyl-5,5-spiro-(3,4-epoxy)cyclohexane-m-dioxane, 1,2:8,9-diepoxylimonene, dicyclopentadienedioxide, cyclooctenedioxide, acetaldiepoxide, vinyl cyclohexanedioxide, vinyl cyclohexenemonooxide 1,2-epoxy-4-vinyl cyclohexane, bis(3,4-epoxycyclohexyl methyl) adipate, bis(3,4-epoxy-6-methyl cyclohexyl methyl) ajipate, exo-exobis(2,3-epoxycyclopentyl) ether, 2,2-bis(4-(2,3-epoxypropyl)cyclohexyl) pronane, 2,6-bis(2,3-epoxypropoxycyclohexyl-p-dioxyane), 2,6-bis(2,3-epoxypropoxy)norbornene, a linoleic acid dimer of diglycidyl ether, limonenedioxide, 2-2-bis(3,4-epoxycyclohexyl) propane, o-(2,3-epoxy)cyclopentyl phenyl-2,3-epoxypropyl ether, 1,2-bis[5-(1,2-epoxy)-4,7-hexahydromethanoinedanxyl]ethane, cyclohexanedioldiglycidyl ether, diglycidyl hexahydrophtalate, ε-caprolactoneoligomer having 3,4-epoxycyclohexyl metanol and 3,4-epoxycyclohexyl carboxylic acid, respectively, bonded to both ends thereof through an ester-bond, epoxydized hexahydrobenzyl alcohol and the like. One kind of these alicyclic epoxy resins or a mixture containing two or more kinds of them is used.

Especially, an alicyclic epoxy resin having one or more epoxycyclohexane rings in a molecular is preferably used as the alicyclic epoxy resin. Among them, as an alicyclic epoxy resin having two epoxycyclohexane rings in a molecular, alicyclic epoxy compounds represented by the following chemical formulas (1), (2) and (3) are preferably used.

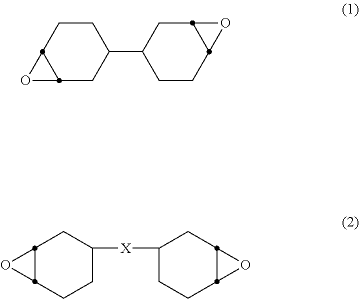

where in the formula (2), “—X-” represents “—O-”, “—S—”, “—SO—”, “—SO₂—”, “—CH₂—”, “—CH(CH₃) —” or “—C(CH₃)₂—”.

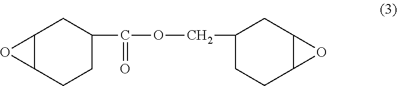 [SMILES: O=C(OCC1CCC2OC2C1)C1CCC2OC2C1]

On the other hand, as an alicyclic epoxy resin having one epoxycyclohexane ring in a molecular, alicyclic epoxy compounds represented by the following chemical formulas (4) and (5) are preferably used.

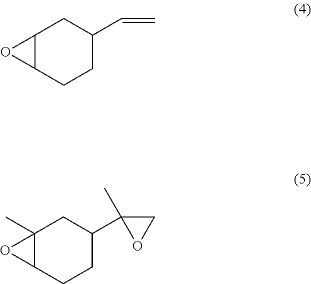

Since such an alicyclic epoxy resin has superior curability at a low temperature, it is possible to carry out a curing treatment thereof at a low temperature. This makes it unnecessary to heat the resin material at a high temperature when being cured, thereby suppressing variation of temperature in a cured product at the time when it is cooled down to room temperature. As a result, it is possible to suppress thermal stress which would be generated due to temperature change inside the first substrate 41, thereby significantly improving optical characteristics of the first substrate 41.

Further, the above mentioned alicyclic epoxy resin has a low coefficient of linear expansion after being cured. Therefore, in the case where the first substrate 41 is formed by impregnating the resin material into a glass cloth, interfacial stress at an interfacial surface between the glass cloth and the resin material becomes significantly small at room temperature. Thus, optical anisotropy of the first substrate 41 becomes small. Further, it is possible to prevent deformations such as warpage and wave undulations of the first substrate 41 due to the low coefficient of linear expansion.

Further, since such an alicyclic epoxy resin has excellent transparency and heat resistance, it contributes to realize a first substrate 41 having excellent optical transparency and high heat resistance.

On the other hand, examples of the alicyclic acryl resin include tricyclodecanyl acrylate, a hydrogenated product thereof, dicyclopentanyl diacrylate, isobornyl diacryalte, hydrogenated bisphenol-A diacrylate, cyclohexane-1,4-dimetanoldiacrylate and the like. Specifically, “OPTOREZ series” produced by Hitachi Chemical Co., Ltd., an acrylate monomer produced by DAICEL-CYTEC Ltd. or the like is used as the alicyclic acryl resin.

The resin material preferably contains these alicyclic epoxy resin and alicyclic acryl resin as a major component thereof. An amount of these resins contained in the resin material is preferably more than 50 mass %, and more preferably 70 mass % or more, and even more preferably 80 mass % or more.

Further, as the resin material, a glycidyl-type epoxy resin is preferably used together with the alicyclic epoxy resin. By using them in combination, it is possible to easily adjust a refractive index of the resin material while suppressing deterioration of the optical characteristics of the first substrate 41. Namely, by appropriately adjusting a mixing ratio of the alicyclic epoxy resin to the glycidyl-type epoxy resin, it is possible to set the refractive index of the resin material to a desired value. As a result, it is possible to obtain a first substrate 41 having superior optical transparency.

In this case, an additive amount of the glycidyl-type epoxy resin is preferably in the range of about 0.1 to 10 parts by mass, and more preferably in the range of about 1 to 5 parts by mass with respect to 100 parts by mass of the alicyclic epoxy resin.

Examples of the glycidyl-type epoxy resin include a glycidyl ether-type epoxy resin, a glycidyl ester-type epoxy resin, a glycidyl amine-type epoxy resin and the like.

As the glycidyl-type epoxy resin, a glycidyl-type epoxy resin having a cardo structure is preferably used. Namely, by adding the glycidyl-type epoxy resin having the carbo structure to the alicyclic epoxy resin and then using the combination thereof, a plurality of aromatic rings derived from a bisaryl fluoren skeleton are contained in the cured resin material. This makes it possible to improve the optical characteristics and the heat resistance of the first substrate 41.

Examples of such a glycidyl-type epoxy resin having the carbo structure include “On Court EX series” (produced by NAGASE & Co., Ltd.) and “OGSOL” (produced by Osaka Gas Chemicals Co., Ltd.).

Further, as the resin material, a silsesquioxane-based compound is preferably used together with the alicyclic epoxy resin. Especially, a silsesquioxane-based compound having a photopolymerizable group such as an oxetanyl group or a (meth)acryloyl group is more preferably used. By using these resins in combination, it is possible to easily adjust the refractive index of the resin material while suppressing the deterioration of the optical characteristics of the first substrate 41. Further, since the silsesquioxane-based compound having the oxetanyl group has high compatibility with respect to the alicyclic epoxy resin, it is possible to uniformly mix these resins with each other. As a result, it is possible to more reliably adjust the refractive index of the resin material, to thereby improve the optical characteristics of the first substrate 41.

Examples of such a silsesquioxane-based compound having the oxetanyl group include “OX-SQ”, “OX-SQ-H” and “OX-SQ-F” (each produced by TOAGOSEI Co., Ltd.) and the like.

In this case, an additive amount of the silsesquioxane-based compound is preferably in the range of about 1 to 20 parts by mass, and more preferably in the range of about 2 to 15 parts by mass with respect to 100 parts by mass of the alicyclic epoxy resin.

Furthermore, a glass-transition temperature of the resin material contained in the first substrate 41 is preferably 150° C. or higher, more preferably 170° C. or higher, and even more preferably 180° C. or higher. This makes it possible to prevent the warpage, the deformation and the like from occurring in the first substrate 41 even if it is subjected to various heat treatments.

Further, a heat distortion temperature of the resin material is preferably 200° C. or higher and a coefficient of thermal expansion of the resin material is preferably 100 ppm/K or less.

Furthermore, the refractive index of the resin material is preferably close to an average refractive index of the glass cloth as possible, and more preferably substantially identical to the average refractive index of the glass cloth. Specifically, a refractive difference between them is preferably 0.01 or less, and more preferably 0.005 or less. This makes it possible to obtain a first substrate 41 having superior optical transparency.

The first substrate 41 may be a resin substrate whose entirety is constituted from the resin material alone or may be a composite substrate containing the resin material and a filling material such as a filler or a cloth. As the first substrate 41, a composite substrate obtained by impregnating the resin material into the glass cloth (fabric) is preferably used. Since thermal expansion is suppressed in such a first substrate 41 (composite substrate), it contributes to restrain warpage of the display element 4 due to temperature change, color deviation thereof due to expansion and shrinkage and the like.

Further, the first substrate 41 may be a single layer or may be a laminated body including a plurality of layers. In the latter case, the resin material contained in each layer may be the same or may be different from each other. Further, the first substrate 41 may be a laminated body including the composite substrate obtained by impregnating the resin material into the glass cloth and the resin layer.

The glass cloth into which the resin material is impregnated is a woven cloth including glass fibers (glass fiber assembly). In this regard, instead of the glass cloth, a glass fabric such as a glass fiber assembly obtained by simply bundling glass fibers or a non-woven cloth (glass fiber assembly) can be used. Examples of weave for the glass cloth include plain weave, basket weave, satin weave, twill weave and the like.

Examples of an inorganic-based glass material constituting the glass fiber include E glass, C glass, A glass, S glass, T glass, D glass, NE glass, quartz, a low-permittivity glass, a high-permittivity glass and the like. Among them, the E glass, the S glass, the T glass or the NE glass is preferably used as the inorganic-based glass material because they contains less ionic impurities such as alkali metals and are easily available. In particular, each of S-glass and T glass having an average coefficient of linear expansion of 5 ppm or less at temperature of 30 to 250° C. is more preferably used.

Further, although a refractive index of the inorganic-based glass material is appropriately set depending on a refractive index of the resin material to be used, it is, for example, preferably in the range of about 1.4 to 1.6, and more preferably in the range of about 1.5 to 1.55. By setting the refractive index of the inorganic-based glass material to be within the above range, it is possible to obtain a first substrate 41 having superior optical characteristics in a broader wavelength range.

An average size (diameter) of the glass fiber contained in the glass cloth is preferably in the range of about 2 to 15 μm, more preferably in the range of about 3 to 12 μm, and even more preferably in the range of about 3 to 10 μm. By setting the average size of the glass fiber to be within the above range, it is possible to provide a first substrate 41 which can exhibit high surface smoothness and superior mechanical or optical characteristics in good balance. In this regard, the average size of the glass fiber can be obtained as an average value of sizes of one hundred glass fibers measured from an observation image taken by observing a cross-sectional surface of the first substrate 41 with a variety of microscopes.

On the other hand, an average thickness of the glass cloth is preferably in the range of about 10 to 200 μm, and more preferably in the range of about 20 to 120 μm. In this regard, in a single first substrate 41, a plurality of glass clothes may be used with being laminated together.

In the case where the glass cloth is a glass woven cloth obtained by weaving bundles (glass yarns) formed of a plurality of glass fibers, the number of the glass fibers in the glass yarn is preferably in the range of 30 to 300, and more preferably in the range of 50 to 250. By setting the number of the glass fibers in the glass yarn to be within the above range, it is possible to obtain a first substrate 41 which can exhibit high surface smoothness and mechanical or optical characteristics in good balance.

It is preferred that such a glass cloth is, in advance, subjected to an opening treatment. By the opening treatment, each glass yarn is widened, to thereby bring a cross-sectional surface thereof into a flatten shape. Further, it is possible to make so-called basket holes existing in the glass cloth smaller. As a result, it is possible to improve smoothness of the glass cloth, thereby improving the surface smoothness of the first substrate 41. Examples of the opening treatment include a water-jet injection treatment, an air-jet injection treatment, a needle punching treatment and the like.

Further, a coupling agent may be applied to a surface of the glass fiber as necessary. Examples of the coupling agent include a silane-based coupling agent, a titanium-based coupling agent and the like. Among them, the silane-based coupling agent is particularly preferably used. As the silane-based coupling agent, a silane-based coupling agent containing a functional group such as an epoxy group, a (meth)acryloyl group, a vinyl group, an isocyanate group or an amide group is preferably used.

A amount of the coupling agent contained in the first substrate 41 is preferably in the range of about 0.01 to 5 parts by mass, more preferably in the range of about 0.02 to 1 parts by mass, and even more preferably in the range of about 0.02 to 0.5 parts by mass with respect to 100 parts by mass of the glass cloth. If the amount of the coupling agent is set to be within the above range, it is possible to improve impregnating ability of the resin material into the glass cloth, to thereby obtain a first substrate 41 having especially good transparency.

An average thickness of the first substrate 41 is preferably in the range of about 0.01 to 3 mm, and more preferably in the range of about 0.03 to 0.25 mm. By setting the average thickness of the first substrate 41 to be within the above range, the first substrate 41 can keep sufficient transparency, bend resistance and impact resistance. Further, the first substrate 41 can exhibit enough mechanical strength for protecting the working unit 43, that is, sufficient resistance against hole-forming or tearing.

Further, it is preferred that the first substrate 41 has bending rigidity lower than the lid body 3. By using the first substrate 41 having the bending rigidity relatively lower than the lid body 3, it is possible to more reliably mitigate the stress concentration with respect to the display element 4 provided on a lower surface of the first substrate 41. On the other hand, since the lid body 3 has bending rigidity larger than the first substrate 41, it is relatively difficult to be bent. This makes it possible to prevent external force from reaching the display element 4 positioned below the lid body 3. In this way, by setting the bending rigidity of the first substrate 41 to become lower than that of the lid body 3, the lid body 3 and the first substrate 41 can reliably protect the working unit 43 by synergistically interacting with each other.

In this regard, in the case where shapes, areas and the like of the first substrate 41 and the lid body 3 in a planar view are the same, a bending rigidity difference therebetween is preferably in the range of about 1 to 90% of the bending rigidity of the lid body 3, and more preferably in the range of about 3 to 80% thereof. If the bending rigidity difference is within the above range, for example, since stress which the first substrate 41 would receive is small as compared with stress which the lid body 3 would receive even when the image display device 1 is bent, the working unit 43 can be reliably protected.

The bending rigidity of the first substrate 41 and the lid body 3 can be adjusted by setting the thicknesses, the shapes or the like thereof in addition to selecting the constituent materials thereof. Therefore, the magnitude correlation of the bending rigidity between the first substrate 41 and the lid body 3 can be adjusted, for example, by making the thickness of the first substrate 41 thinner when using a material of the first substrate 41 whose bending elastic moduli is large, or by making the thickness of the lid body 3 thicker when using a material of the lid body 3 whose bending elastic moduli is small.

Further, a bending elastic moduli (25° C.) defined by JIS K 7171 of a constituent material of the first substrate 41 is not limited to a specific value, but is preferably in the range of about 1 to 30 GPa, and more preferably in the range of about 2 to 28 GPa. The first substrate 41 constituted from such a material has moderate flexibility and moderate rigidity. Therefore, it is possible to exhibit the mitigation of the stress concentration with respect to the first substrate 41 due to the moderate flexibility and the bend resistance of the first substrate 41 due to the moderate rigidity in a high degree, to thereby more reliably protect the working unit 43.

On the other hand, the second substrate 42 shown in FIG. 1 has only to be transparent, but is preferably the same substrate as the above mentioned first substrate 41. Namely, it is preferred that the second substrate 42 shown in FIG. 1 has transparency and flexibility. Such a second substrate 42 effectively transmits light from backlight 45 provided at the lowermost part of the display element 4, and thus contributes to display a clear image of the display element 4.

Further, it is preferred that the second substrate 42 is similar to the first substrate 41 with regard to characteristics such as the bending rigidity and the coefficient of thermal expansion. In this case, it is possible to mitigate the stress concentration with respect to the display element 4 which would occur when the difference therebetween in these characteristics is large.

Furthermore, as the second substrate 42, the composite substrate obtained by impregnating the resin material into the glass cloth is also preferably used. Since the electrical circuit including the pixel electrodes and the transistors is generally formed on the second substrate 42, a substrate whose coefficient of thermal expansion is suppressed using the glass cloth is suitable from the viewpoint of preventing breaking of wire and the like.

In this regard, the above description is made on the case where the display element 4 is the liquid crystal display element, but the configuration of the display element 4 is appropriately selected depending on the kind of the display element 4. For example, if the display element 4 is a self-emitting light type element such as the organic EL element, the second substrate 42 may be opacity (not transparent) or may be omitted. In the case where the second substrate 42 is omitted, the electrical circuit for operating the working unit 43 is provided on the side of the first substrate 41.

Further, a gas barrier layer may be provided on each of the first substrate 41 and the second substrate 42. By providing the gas barrier layer, it is possible to suppress moisture and oxygen from passing through the first substrate 41 and the second substrate 42, to thereby reduce alternation and degradation of the working unit 43.

As the gas barrier layer, various inorganic oxide layers are preferably used, and a silicon compound layer is further preferably used. By providing such a gas barrier layer, it is possible to reduce water vapor permeability and oxygen permeability of the display element 4 without degrading the optical characteristics thereof.

Further, the first polarizing plate 44 is provided above the first substrate 41 and the second polarizing plate 46 is provided below the second substrate 42, respectively.

Each of the first polarizing plate 44 and the second polarizing plate 46 is of a film-like shape and controls polarizing of light passing therethrough. Each of the first polarizing plate 44 and the second polarizing plate 46 is formed from a laminated film including a plurality of layers, and a constituent material of each layer is appropriately selected from translucent resin materials depending on functions thereof. Examples of the translucent resin materials include a polyethylene-based resin, a polyvinyl alcohol (PVA)-based resin, a triachetyl cellulose (TAC)-based resin, a cyclic polyolefine-based resin, a (meth)acryl-based resin, a polyester-based resin such as polyethylene terephthalate and the like.

Further, as each of the first polarizing plate 44 and the second polarizing plate 46, a film having flexibility is preferably used. In this case, when the image display device 1 is bent, the first polarizing plate 44 and the second polarizing plate 46 can be also bent together with the lid body 3, the first substrate 41 and the second substrate 42. Therefore, it becomes difficult to cause peeling-off between the respective parts. As a result, even if the image display device 1 is bent, the image display device 1 can keep displaying a clear image.

Further, the backlight 45 has a light source and a light guide plate. Light from the light source is equalized in the in-plane of the display element 4 by the light guide plate and is emitted upward. As the light source, a cold cathode fluorescent lamp, a light-emitting diode or the like is used. Further, as a constituent material of the light guide plate, for example, the same material as the constituent material of the above mentioned polarizing plate is used. Therefore, as this light guide plate, the film (sheet) having the flexibility is also preferably used.

(Lid Body)

The lid body (plate-like opposite substrate) 3 is provided on an upper side of the housing 2 opposite to the bottom portion 22, and is fixed on the housing 2 so as to cover the storage portion 21.

The lid body 3 is of substantially the same shape as the housing 2 (bottom portion 22) in a planer view thereof. Then, by bonding the lid body 3 to an upper end surface of the peripheral portion 23 of the housing 2, the lid body 3 covers the storage potion 21 as an enclosed space.

As described above, the lid body 3 has the transparency and the flexibility. Therefore, the lid body 3 can mitigate the stress concentration with respect to the display element 4, and thus can improve the bend resistance and the impact resistance of the entirety of the image display device 1.

In this regard, a transparent degree of the lid body 3 and the above mentioned first substrate 41 can be, for example, defined based on total light transmittance described in JIS K 7105. Specifically, in the case where the total light transmittance of the lid body 3 and the above mentioned first substrate 41 is 80% or more, they are determined to have the transparency.

Further, the “flexibility” of the lid body 3 and the above mentioned first substrate 41 means that they can be bent without being crashed. Specifically, in the case where when a lid body 3 having a size of 300 mm square is formed, and then is bent so that a curvature radius thereof becomes 100 mm, it is not crashed, the lid body 3 is determined to have the flexibility.

In this embodiment, the lid body 3 contains the resin material. The lid body 3 containing the resin material has excellent flexibility and becomes light weight. Therefore, by reducing the weight of the lid body 3, the weight of the image display device 1 is also reduced. As a result, the image display device 1 can exhibit excellent portability suitable for being held for long period of time.

Further, by reducing the weight of the image display device 1, it is also possible to weaken the impact which would be applied to the image display device 1 when it is dropped from a high altitude. This makes it possible to decrease the impact strength to the display element 4 due to the drop, to thereby prevent the working unit 43 from being destroyed.

Furthermore, the lid body 3 containing the resin material also has an advantage in that it is easy to form a predetermined shape. For example, operation buttons for operating the image display device 1 are sometimes provided on the lid body 3. These operation buttons are provided so as to pass through the lid body 3 and connected with the electrical circuit provided below the lid body 3. In order to form through-holes for arranging such operation buttons, a conventional glass substrate was required to be subjected to a hole making process. In this case, the glass substrate was sometimes crashed or strength thereof was decreased.

However, since the lid body 3 containing the resin material is difficult to be crashed, the through-holes can be easily formed therethrough. Further, at this time, strength of the lid body 3 is hardly decreased. Therefore, a plurality of operation buttons can be closely arranged on the lid body 3, which makes it possible to improve a degree of freedom of the arrangement of the operation buttons.

Configurations of the lid body 3 include (i) a resin substrate formed of only a resin material, (ii) a composite substrate obtained by impregnating a resin material into a glass cloth, and the like. Hereinafter, these configurations of the lid bodies 3 will be described in order.

(i) Resin Substrate Formed of Only Resin Material

In this case, the resin material contained in the lid body 3 is not limited to a specific kind as long as it is a transparent material. Examples of the resin material include a (meth)acryl-based resin, an epoxy-based resin, a polystyrene-based resin, a polycarbonate-based resin, AS resin, a soft polyvinyl chloride-based resin and the like. One kind of these transparent materials or a mixture containing two or more kinds of them is used. Further, for the lid body 3, especially, a resin material containing the (meth)acryl-based resin or the polycarbonate-based resin as a major component thereof is preferably used.

Since the lid body 3 containing such a resin material has especially high transparency, it is possible for the image display device 1 to display a clear image. Further, these resin materials have excellent flexibility and relatively high strength. Therefore, it is possible to make the lid body 3 thinner. This makes it possible to obtain a lid body 3 having the transparency, the bend resistance and the impact resistance in an especially superior degree, and very light weight.

An average thickness of the lid body 3 is preferably in the range of about 0.02 to 0.8 mm, and more preferably in the range of about 0.05 to 0.5 mm. By setting the average thickness of the lid body 3 to be within the above range, the lid body 3 can sufficiently keep the transparency, the bend resistance and the impact resistance. Further, the lid body 3 can exhibit enough mechanical strength for protecting the display element 4, that is, sufficient resistance against hole-forming or tearing.

Further, a bending elastic moduli (25° C.) defined by JIS K 7171 of a constituent material of the lid body 3 is not limited to a specific value, but is preferably in the range of about 0.5 to 30 GPa, and more preferably in the range of about 1 to 28 GPa. The lid body 3 constituted from such a material has moderate flexibility and moderate rigidity. Therefore, it is possible to exhibit mitigation of stress concentration with respect to the lid body 3 due to the moderate flexibility and the bend resistance of the lid body 3 due to the moderate rigidity in a high degree, to thereby more reliably protect the working unit 43.

In this regard, the lid body 3 may be a single layer or may be a laminated body including a plurality of layers. In the latter case, the resin material contained in each layer may be the same or may be different from each other. However, preferable is a laminated body including a layer defining the display surface (topmost layer in FIGS. 1 and 2) and constituted from a material having relatively high hardness, and another layers whose one layer is constituted from a material having relatively low hardness. By such a configuration, it is possible to obtain a lid body 3 having excellent flexibility and keeping abrasion resistance of the display surface. Specifically, examples of the material having relatively high hardness include polycarbonate-based resin, whereas examples of the material having relatively low hardness include polyethylene terephthalate resin or (meth)acryl-based resin.

(ii) Composite Substrate Obtained by Impregnating Resin Material into Glass Cloth

As the lid body 3 having such a configuration, the same composite substrate as the above mentioned first substrate 41 can be used.

In this regard, an average thickness of the lid body 3 having such a configuration is preferably in the range of about 0.02 to 0.8 mm, and more preferably in the range of about 0.05 to 0.5 mm as described above.

Further, a touch panel electrode 31 is provided below the lid body 3. This touch panel electrode 31 is a part constituting an input unit having a touch panel system (touch panel input unit) of the image display device 1. The image display device 1 includes a laminated body in which electrodes for detecting a position along a X-axial direction of the display surface and electrodes for detecting a position along a Y-axial direction thereof are laminated together through an insulating layer, and among these electrodes, one of the electrodes serves as the touch panel electrode 31.

Such a touch panel system is referred to as a capacitance type touch panel system. Namely, the image display device 1 is equipped with an input unit having a capacitance type touch panel system (capacitance type touch panel input unit). The capacitance type touch panel input unit detects a position (coordinate) of the display surface touched by a finger of a user by taking small change of capacitance which would occur between the electrodes when the finger touches it. Then, input operation is curried out based on this detected position. Since the change of capacitance is a little as compared with capacitance of background, sensitivity of the input unit is influenced by whether or not such change is correctly taken.

As described above, the lid body 3 is formed of the resin material, and thus has the flexibility. Since such a lid body 3 is difficult to be crashed unlike a thick glass substrate, the lid body 3 can be safely used even if it is made so as to have a sufficiently thin thickness. By using such a thin lid body 3, it is possible to increase a change amount of capacitance which would occur when the finger touches the display surface. As a result, it is possible to form a touch panel input unit having high sensitivity. Further, by making the lid body 3 thin, it is also possible to reduce the weight and the transparency of the image display device 1.

In this regard, examples of a type of the position detection by the touch panel input unit include, but are not especially limited to, a resistance film type, a surface acoustic wave type, an infrared type, a strain gauge type, a light image processing type, a dispersion signal type, a sound type and the like, in addition to the capacitance type.

Further, this touch panel input unit may be provided on the lid body 3 in this embodiment, but may be provided on the display element 4. In the latter case, a laminated body including two electrode layers and an insulating layer provided therebetween is laminated on the display element 4. In this case, a configuration of the laminated body functioning as the touch panel input unit may be the same as the above. Further, the first polarizing plate 44 itself may be used as the insulating layer.

Moreover, the laminated body may be formed by using the first polarizing plate 44 as the insulating layer, forming one touch panel electrode on a lower surface of the lid body 3 and forming the other touch panel electrode on a lower surface of the first polarizing plate 44. In this case, a part of the touch panel input unit is provided on a side of the lid body 3 and the rest thereof is provided on a side of the display element 4.

Especially, if the lid body 3 is formed from the composite substrate, permittivity of the lid body 3 becomes high as compared with a substrate (formed of only resin material). Therefore, in the case where the lid body 3 is equipped with the capacitance type touch panel input unit, it is possible to increase the change amount of capacitance when touch-operating, to thereby especially improve the sensitivity thereof as the input unit.

In this regard, in the case where the lid body 3 contains an inorganic filler, it is also possible to increase the permittivity thereof. Examples of the inorganic filler include a glass filler, a silica filler and the like.

(Battery)

The battery 5 shown in FIG. 1 is an electrical source supplying an electrical power for driving the display element 4 and the touch panel input unit (input device).

As the battery 5, various kinds of secondary batteries such as a lithium ion battery and a nickel hydoride battery, capacitors and the like are preferably used, but a lithium ion battery utilizing a polymer gel technology for an electrolyte thereof is especially preferably used. Since this lithium ion battery is immune from leaking of the electrolyte, an exterior formed from a film laminate can be used. Therefore, it is possible to make the lithium ion battery drastically thinner and lighter, and to also impart flexibility to the lithium ion battery.

(Control Unit)

The control unit 6 shown in FIG. 1 contains a central processing unit (CPU), a memory (RAM), a flash memory, a communication unit, a display controller, a touch panel controller and the like. The central processing unit produces a necessary image by executing a program on the memory and the like. Further, the display controller changes image data generated by a program and the like into display signal and outputs it at the display element 4. Further, the touch panel controller detects operation of the touch panel input unit, and then transmits a result thereof to the operation unit.

In this regard, each part of above mentioned control unit 6 also may be mounted on a wiring substrate having flexibility. In this case, it is possible to impart flexibility to the entirety of the image display device 1. For example, examples of the wiring substrate having flexibility include a flexible printed circuit substrate (FPC) and the like.

Further, the image display device 1 may be equipped with a camera (image pickup element), a speaker, a vibrator, a flashlight, an infrared light receiving and emitting unit and the like. Operation of them is controlled by the control unit 6.

In this regard, examples of the image display device 1 include a tablet type personal computer (tablet type PC), a tablet type handheld device, a smart phone, an electronic paper, a portable type game machine, a PDA (Personal Digital Assistant), a digital photo frame, a navigation system and the like.

According to the first embodiment described above, each of the lid body 3 and the first substrate 41 has the transparency and the flexibility, and contains the resin material. Therefore, the weight of the image display device 1 can be reduced, as a result of which the image display device 1 can exhibit excellent portability suitable for being held for a long period of time. Further, since the impact against the image display device 1 is reduced when being dropped by reducing the weight thereof, it is possible to decrease failure probability of the image display device 1 due to the drop.

Since each of the lid body 3 and the first substrate 41 has the flexibility, it is possible to improve the durability and the impact resistance of the image display device 1 against the deformation such as the bend thereof. The stress concentration to the working unit 43 is hardly generated even if the image display device 1 is bent or dropped. This makes it possible to suppress the breakage of the working unit 43.

Further, since each of the lid body 3 and the first substrate 41 is difficult to be crashed, the safety thereof is kept even if it is made thinner. Therefore, by making each of the lid body 3 and the first substrate 41 thinner, it is possible to further improve the flexibility and the transparency thereof. Further, since the lid body 3 can be easily processed, the operation buttons and the like can be freely arranged thereon.

Furthermore, in the case where the lid body 3 is equipped with the capacitance type touch panel input unit, it is possible to improve the sensitivity of the touch position detection. This makes it possible to obtain an image display device 1 capable of being comfortably operated.

### Second Embodiment

Hereinafter, description will be made on an image display device 1 of a second embodiment with a focus on the points differing from the image display device 1 of the first embodiment, with the same points being omitted from the description.

The image display device 1 of the second embodiment is the same as the image display device 1 of the above mentioned first embodiment, except that the configuration of the first substrate 41 is different from each other.

In this embodiment, the lid body 3 contains a resin material, whereas the first substrate 41 contains a plate-like glass base member and has a very small average thickness of 0.02 to 0.2 mm. Therefore, since the lid body and the first substrate 41 have very light weight as compared with a case where they are constituted from a thick glass substrate, it is possible to reduce weight of the image display device 1.

Further, each of the lid body 3 and the first substrate 41 has flexibility. Therefore, the lid body 3 and the first substrate 41 have excellent durability against deformation such as bend and high impact resistance. As a result, the lid body 3 and the first substrate 41 can mitigate stress concentration with respect to the display element 4 and the like, to thereby prevent the working unit 43 of the display element 4 from being destroyed when the image display device 1 is dropped.

The first substrate 41 contains the plate-like glass base member and has the average thickness of 0.02 to 0.2 mm. In the case where the first substrate 41 contains the glass base member and has very thin thickness, it has excellent flexibility and becomes light weight. Therefore, by reducing the weight of the first substrate 41, the weight of the image display device 1 is also reduced. As a result, the image display device 1 can exhibit excellent portability suitable for being held for a long period of time.

Further, by reducing the weight of the image display device 1, it is also possible to weaken impact which would be applied to the image display device 1 when it is dropped from a high altitude. This makes it possible to decrease impact strength to the display element 4 due to the drop, to thereby prevent the working unit 43 from being destroyed.

In this regard, although such a first substrate 41 contains the glass base member, it is made so as to have the small average thickness of 0.02 to 0.2 mm. As a result, impact resistance of the first substrate 41 is significantly improved. Therefore, the first substrate 41 is difficult to be crashed unlike a thick glass substrate, and thus can be safely used. Further, by making the first substrate 41 thinner, it is possible to reduce the weight of the first substrate 41 and to improve the transparency thereof.

Moreover, since the glass base member is contained in the first substrate 41 even if it is made thinner up to the above mentioned thickness, water vapor permeation and oxygen permeability thereof can be made very small. This makes it possible to reliably suppress deterioration and alternation of the working unit 43 due to moisture or oxygen, to thereby make life of the image display device 1 longer.

In this regard, the average thickness of the first substrate 41 is preferably in the range of 0.04 to 0.15 mm, and more preferably in the range of 0.05 to 0.12 mm.

Examples of a constituent material of the glass base member of the first substrate 41 include various kinds of inorganic glass materials such as silica glass, soda lime quartz glass, lead glass, borosilicate glass, alkali-free glass, quartz glass. Among them the alkali-free glass is especially preferably used. Since the glass base member constituted from the alkali-free glass contains no alkali oxide, it has excellent heat resistance, superior electrical insulating properties and low thermal expansion.

For this reason, even in the case where the first substrate 41 is subjected to a heat treatment at a high temperature, for example, when the display element 4 is produced, it is possible to suppress deterioration, alternation or the like of the first substrate 41 from occurring. Further, even in the case where an electrical circuit (e.g., a TFT circuit, a touch panel circuit and the like) is formed on a surface of the first substrate 41, it is possible to reliably prevent short circuit or the like from occurring, to thereby obtain a display element 4 capable of stably driving.

Further, the first substrate 41 may be a glass substrate constituted from only the glass base member or may be a compound substrate including the glass base member and a resin layer laminated thereon. In the case where the first substrate 41 is such a compound substrate, even if cracks are generated in the glass base member, it is possible to prevent the cracks from being developed due to the existence of the resin layer to not scatter fragments and the like. This makes it possible to prevent the working unit 43 from being destroyed by the fragments and the like of the glass base member.

Examples of a constituent material of the resin layer include: thermoplastic resins such as a polyester-based resin, polyetherimide, polyalylate, polymethyl methacrylate, polyethersulfone, polysulphone, polyetheretherketone, an aliphatic cyclic polyolefine-based resin, a polycarbonate-based resin and a polyimide-based resin; and energy-curable resins such as an epoxy-based resin, an oxetane-based resin, an isocyanate-based resin, an acrylate-based resin, a phenol-based resin, a polyfunctional olefin-based resin, a diallyl phthalate-based resin, a diallyl carbonate-based resin, an urethane-based resin, a melamine-based resin, a silsesquioxane-based compound. One kind of these resins or a mixture containing two or more kinds of them is used.

By using these resins, it is possible to obtain a resin layer having excellent adhesion with regard to the glass base member. This makes it possible to prevent the resin layer from being peeled off from the glass base member, for example, even when the image display device 1 is bent.

An average thickness of the resin layer is set depending on a balance with a thickness of the glass base member and a total thickness of the first substrate 41, but is, for example, preferably in the range of about 0.0002 to 0.05 mm, and more preferably in the range of about 0.001 to 0.02 mm.

Further, a ratio of the thickness of the resin layer with respect to the total thickness of the first substrate 41 is preferably in the range of about 1 to 70%, and more preferably in the range of about 5 to 50%. By setting the ratio of the thickness of the resin layer to be within the above range, the resin layer can highly exhibit both optical characteristics and a developing prevention feature of cracks. Further, in this case, it is possible to suppress deformation of the first substrate 41 which would be generated due to a difference between coefficients of thermal expansion of the glass base member and the resin layer in such a small degree that the image display device 1 can be used with no problem.

In this regard, the resin layer may contain arbitrary additives if needed. Examples of such additives include a diluent, an antioxidant, a denaturant, a surfactant, a colorant, a pigment, a discoloration inhibitor, an UV absorber, a softener, a stabilizer, a plasticizer, an antifoam, a stiffener and the like.

Further, a coupling agent layer may be provided between the glass base member and the resin layer if needed. By providing the coupling agent layer, it is possible to more firmly bond the resin layer to the glass base member. Examples of a coupling agent constituting the coupling agent layer include a silane coupling agent, a titanium coupling agent and the like.

Examples of a method of forming the coupling agent layer include a method in which a solution containing the coupling agent is applied onto a surface of the glass base member, and then subjected to a heat treatment.

The solvent used for preparing the solution is not limited to a specific kind as long as it does not react with the coupling agent. Examples of the solvent include an aliphatic hydrocarbon-based solvent such as hexane, an aromatic-based solvent such as benzene, toluene or xylene, an ether-based solvent such as tetrahydrofuran, an alcohol-based solvent such as methanol or propanol, a ketone-based solvent such as acetone, water and the like. One kind of these solvents or a mixture containing two or more kinds of them is used.

Further, as a method of applying the solution, used are, for example, various kinds of a coating method such as a doctor-blade method, a knife coating method, a spray coating method, a roll coating method, a cast coating method, a dip coating method and a die coating method.

On the other hand, a method of forming the resin layer include a method in which a liquid film is obtained by applying a solution containing the resin material, and then dried.

A drying temperature is set to about 80 to 200° C. and a drying time is set to about 1 to 60 minutes. Further, a solvent and a method of applying a solution are the same as described above.

According to the second embodiment described above, each of the lid body 3 and the first substrate 41 has the transparency and the flexibility, the lid body 3 contains the resin material, and the first substrate 41 contains the glass base member and has the average thickness of 0.02 to 0.2 mm. Therefore, the weight of the image display device 1 can be reduced, as a result of which the image display device 1 can exhibit excellent portability suitable for being held for a long period of time. Further, since the impact against the image display device 1 is reduced when being dropped by reducing the weight thereof, it is possible to decrease failure probability of the image display device 1 due to the drop.

Since each of the lid body 3 and the first substrate 41 has the flexibility, it is possible to improve the durability and the impact resistance of the image display device 1 against the deformation such as the bend thereof. The stress concentration to the working unit 43 is hardly generated even if the image display device 1 is bent or dropped. This makes it possible to suppress the breakage of the working unit 43.

Further, since each of the lid body 3 and the first substrate 41 has the flexibility and thus is difficult to be crashed unlike a thick glass substrate, the safety thereof is kept. Further, since the lid body 3 can be easily processed, the operation buttons and the like can be freely arranged thereon.

Furthermore, since the lid body 3 can be made enough thin, in the case where the lid body 3 is equipped with the capacitance type touch panel input unit, it is possible to improve the sensitivity of the touch position detection. This makes it possible to obtain an image display device 1 capable of being comfortably operated.

Further, from the same reason as described in the first embodiment, it is preferred that the second substrate 42 is also the same substrate as the first substrate 41 in the second embodiment. In addition, it is also preferred that the second substrate 42 has characteristics such as flexibility and coefficient of thermal expansion equal to the first substrate 41.

### Third Embodiment

Hereinafter, description will be made on an image display device 1 of a third embodiment with a focus on the points differing from the image display devices 1 of the first and second embodiments, with the same points being omitted from the description.

The image display device 1 of the third embodiment is the same as the image display device 1 of the above mentioned first embodiment, except that the configuration of the lid body 3 is different from each other.

In this embodiment, the lid body 3 contains a plate-like glass base member and has a very small average thickness of 0.02 to 0.2 mm, whereas the first substrate 41 contains a resin material. Therefore, since the lid body 3 and the first substrate 41 have very light weight as compared with a case where they are constituted from a thick glass substrate, it is possible to reduce weight of the image display device 1.

Further, each of the lid body 3 and the first substrate 41 has flexibility. Therefore, the lid body 3 and the first substrate 41 have excellent durability against deformation such as bend and high impact resistance. As a result, the lid body 3 and the first substrate 41 can mitigate stress concentration with respect to the display element 4 and the like, to thereby prevent the working unit 43 of the display element 4 from being destroyed when the image display device 1 is dropped.

The lid body 3 contains the plate-like glass base member and has the average thickness of 0.02 to 0.2 mm. In the case where the lid body 3 contains the glass base member and has very thin thickness, it has excellent flexibility and becomes light weight. Therefore, by reducing the weight of the lid body 3, weight of the image display device 1 is also reduced. As a result, the image display device 1 can exhibit excellent portability suitable for being held for a long period of time.

Further, by reducing the weight of the image display device 1, it is also possible to weaken impact which would be applied to the image display device 1 when it is dropped from a high altitude. This makes it possible to decrease impact strength to the display element 4 due to the drop, to thereby prevent the working unit 43 from being destroyed.

In this regard, although such a lid body 3 contains the glass base member, it is made so as to have the small average thickness of 0.02 to 0.2 mm. As a result, impact resistance of the lid body 3 is significantly improved. Therefore, the lid body 3 is difficult to be crashed unlike a thick glass substrate, and thus can be safely used. Further, by making the lid body 3 thinner, it is possible to reduce the weight of the lid body 3 and to improve of the transparency thereof.

Moreover, since the glass base member is contained in the lid body 3 even if it is made thinner up to the above mentioned thickness, water vapor permeation and oxygen permeability thereof can be made very small. This makes it possible to reliably suppress deterioration and alternation of the working unit 43 due to moisture or oxygen, to thereby make life of the image display device 1 longer.

In this regard, the average thickness of the lid body 3 is preferably in the range of 0.04 to 0.15 mm, and more preferably in the range of 0.05 to 0.12 mm.

Examples of a constituent material of the glass base member of the lid body 3 include the same constituent material of the glass base member contained in the first substrate 41 of the above mentioned second embodiment. For this reason, even in the case where the lid body 3 is subjected to a heat treatment at a high temperature, for example, when the capacitance type touch panel input unit is formed on the lid body 3, it is possible to suppress deterioration, alternation or the like of the lid body 3 from occurring. Further, even in the case where an electrical circuit (e.g., a TFT circuit, a touch panel circuit and the like) is formed on a surface of the lid body 3, it is possible to reliably prevent short circuit or the like from occurring, to thereby obtain a display element 4 capable of stably driving.

Further, the lid body 3 may be a glass substrate constituted from only the glass base member or may be a compound substrate including the glass base member and a resin layer laminated thereon like the first substrate 41 of the above mentioned second embodiment. In the case where the lid body 3 is such a compound substrate, even if cracks are generated in the glass base member, it is possible to prevent the cracks from being developed due to the existence of the resin layer to not scatter fragments and the like. This makes it possible to prevent the working unit 43 from being destroyed by the fragments and the like of the glass base member.

Examples of a constituent material of the resin layer include the same constituent material of the resin layer contained in the first substrate 41 of the above mentioned second embodiment.

As described above, the lid body 3 contains the glass base member, has the average thickness of 0.02 to 0.2 mm, and has the flexibility. Since such a lid body 3 is difficult to be crashed unlike a thick glass substrate by being easily bent, and thus can be safely used. Further, by using such a thin lid body 3, it is possible to increase a change amount of capacitance which would occur when the finger touches the display surface. As a result, it is possible to obtain a touch panel input unit having high sensitivity. Further, by making the lid body 3 thin, it is also possible to reduce the weight and the transparency of the image display device 1.

Furthermore, since the lid body 3 contains the glass base member, the lid body 3 has high hardness, and thus exhibits excellent abrasion resistance. Therefore, even if an upper surface (display surface) of the lid body 3 are repeatedly rubbed or tapped with a finger and the like, it is possible to prevent abrasion of the lid body 3. In addition to this, high texture peculiar to a glass material can be imparted to the display surface of the image display device 1. As a result, it is possible to improve sense when the finger touches the display surface of the image display device 1, to thereby create luxurious feel.

Moreover, since the lid body 3 contains the glass base member, permittivity of the lid body 3 becomes high as compared with a case where the lid body 3 is formed of only a resin material. Therefore, in the case where the lid body 3 is equipped with the capacitance type touch panel input unit, it is possible to increase the change amount of capacitance when touch-operating, to thereby especially improve the sensitivity thereof as the input unit.

According to the third embodiment described above, each of the lid body 3 and the first substrate 41 has the transparency and the flexibility, the lid body 3 contains the glass base member and has the thickness of 0.02 to 0.2 mm, and the first substrate 41 contains the resin material. Therefore, the weight of the image display device 1 can be reduced, as a result of which the image display device 1 can exhibit excellent portability suitable for being held for a long period of time. Further, since impact against the image display device 1 is reduced when being dropped by reducing the weight thereof, it is possible to decrease failure probability of the image display device 1 due to the drop.

Since each of the lid body 3 and the first substrate 41 has the flexibility, it is possible to improve the durability and the impact resistance of the image display device 1 against the deformation such as the bend thereof. The stress concentration to the working unit 43 is hardly generated even if the image display device 1 is bent or dropped. This makes it possible to suppress the breakage of the working unit 43.

Further, since each of the lid body 3 and the first substrate 41 has the flexibility, and thus is difficult to be crashed unlike a thick glass substrate, the safety thereof is kept.

Furthermore, since the lid body 3 is made enough thin, in the case where the lid body 3 is equipped with the capacitance type touch panel input unit, it is possible to improve the sensitivity of the touch position detection. This makes it possible to obtain an image display device 1 capable of being comfortably operated. In addition, this makes it possible to improve the abrasion resistance and the texture of the display surface of the image display device 1.

Further, from the same reason as described in the first embodiment, it is preferred that the second substrate 42 is also the same substrate as the first substrate 41 in the third embodiment. In addition, it is also preferred that the second substrate 42 has characteristics such as flexibility and coefficient of thermal expansion equal to the first substrate 41.

### Fourth Embodiment

Hereinafter, description will be made on an image display device 1 of a fourth embodiment with a focus on the points differing from the image display devices 1 of the first to third embodiments, with the same points being omitted from the description.

The image display device 1 of the fourth embodiment is the same as the image display device 1 of the above mentioned first embodiment, except that the configurations of the lid body 3 and the first substrate 41 are different from each other.

In this embodiment, each of the lid body 3 and the first substrate 41 contains a plate-like glass base member and has a very small average thickness of 0.02 to 0.2 mm. Therefore, since the lid body 3 and the first substrate 41 have very light weight as compared with a case where they are constituted from a thick glass substrate, it is possible to reduce weight of the image display device 1.

Further, each of the lid body 3 and the first substrate 41 has flexibility. Therefore, the lid body 3 and the first substrate 41 have excellent durability against deformation such as bend and high impact resistance. As a result, the lid body 3 and the first substrate 41 can mitigate stress concentration with respect to the display element 4 and the like, to thereby prevent the working unit 43 of the display element 4 from being destroyed when the image display device 1 is dropped.

In this regard, the first substrate 41 of the fourth embodiment is formed so as to have the same configuration as the first substrate 41 of the above mentioned second embodiment, and the lid body 3 of the fourth embodiment is formed so as to have the same configuration as the lid body 3 of the above mentioned third embodiment.

According to the fourth embodiment described above, each of the lid body 3 and the first substrate 41 has the transparency and the flexibility, contains the glass base member and has the average thickness of 0.02 to 0.2 mm. Therefore, the weight of the image display device 1 can be reduced, as a result of which the image display device 1 can exhibit excellent portability suitable for being held for a long period of time. Further, since impact against the image display device 1 is reduced when being dropped by reducing the weight thereof, it is possible to decrease failure probability of the image display device 1 due to the drop.

Since each of the lid body 3 and the first substrate 41 has the flexibility, it is possible to improve the durability and the impact resistance of the image display device 1 against the deformation such as the bend thereof. The stress concentration to the working unit 43 is hardly generated even if the image display device 1 is bent or dropped. This makes it possible to suppress the breakage of the working unit 43.

Further, since each of the lid body 3 and the first substrate 41 has the flexibility, and thus is difficult to be crashed unlike a thick glass substrate, the safety thereof is kept.

Furthermore, since the lid body 3 is made enough thin, in the case where the lid body 3 is equipped with the capacitance type touch panel input unit, it is possible to improve the sensitivity of the touch position detection. This makes it possible to obtain an image display device 1 capable of being comfortably operated. In addition, this makes it possible to improve the abrasion resistance and the texture of the display surface of the image display device 1.

Further, from the same reason as described in the first embodiment, it is preferred that the second substrate 42 is also the same substrate as the first substrate 41 in the fourth embodiment. In addition, it is also preferred that the second substrate 42 has characteristics such as flexibility and coefficient of thermal expansion equal to the first substrate 41.

While the embodiments according to the present invention have been described, the present invention is not limited thereto. For example, arbitrary structures may be added to the image display devices according to the above mentioned embodiments.

For example, in the housing 2, the bottom portion 22 and the peripheral portion 23 may be formed from separate members. In this case, the bottom portion 22 and the peripheral portion 23 may be formed of the same material or may be formed of different materials. Further, in this case, the peripheral portion 23 may be constituted from a plurality of block bodies (spacers) arranged at certain intervals between the bottom portion (plate-like base substrate) 22 and the lid body (opposite substrate) 3 along peripheries thereof, and sealing members or a sealant (adhesive) for sealing spaces between the block bodies.

Further, the first substrate 41 and the second substrate 42 may be formed from different substrates. However, as described above, as the first substrate 41 and the second substrate 42, used are preferably similar (substantially same) substrates. Therefore, in each of the above embodiments, the description has been made by defining the first substrate 41 and the second substrate 42 as the element substrate and the opposite element substrate, respectively. In contrast, the first substrate and the second substrate 42 may be defined as the opposite element substrate and the element substrate, respectively.

### EXAMPLES

Next, description will be made on concrete examples of the present invention.

### 1. Manufacture of Image Display Device

### Example 1a

### (1) Housing, Battery and Control Unit

First, a housing made of ABS resin was prepared. A size of the housing in a planar view thereof was 242 mm×186 mm.

Next, a polymer gel lithium ion battery and an electrical circuit substrate on which a CPU and a memory and the like were mounted on (control unit) were put into a storage portion of the housing.

### (2) Production of Liquid Crystal Display Element

Next, produced was a liquid crystal display element in which respective parts such as a first polarizing plate, a first substrate, a liquid crystal layer (working unit), a second substrate, a second polarizing plate and a backlight were laminated together as follows. In this regard, as each of the first polarizing plate and the second polarizing plate, used was a PVA polarizing film having an average thickness of 0.1 mm. Further, an average thickness of the backlight was 0.4 mm.

As each of the first substrate and the second substrate, used was a composite substrate obtained by impregnating a resin material into a glass cloth. These first substrate and second substrate were produced as follows.

First, as the glass cloth, prepared was a NE glass-type glass cloth (having an average thickness of 95 μm and an average fiber size of 9 μm).

On the other hand, prepared was a resin varnish by mixing 96 parts by mass of an alicyclic epoxy resin (“E-DOA” produced by Daicel Chemical Industries, Ltd.), 4 parts by mass of silsesquioxane (“OX-SQ-H” produced by TOAGOSEI Co., Ltd.), 1 part by mass of a photocationic polymerization initiator (“SP-170” produced by ADEKA Corporation) and 25.25 parts by mass of a solvent (methyl isobutyl ketone). A refractive index of the E-DOA after being cross-linked was 1.513 and a refractive index of the OX-SQ-H after being cross-linked was 1.47.

Thereafter, the glass cloth was impregnated into the prepared resin varnish, and then subjected to a defoaming treatment. Then, the resin varnish was dried. In this way, obtained was a dried product of the resin varnish containing the glass cloth.

Next, this dried product was put between two glass plates subjected to a releasing treatment and irradiated with an ultraviolet ray having 1100 mJ/cm² using a high pressure mercury lamp. Moreover, the dried product was heated at 250° C. for 2 hours, to thereby obtain a composite substrate having an average thickness of 100 μm (amount of glass cloth was 57 mass %). The obtained composite substrate had transparency and flexibility.

Thereafter, an active matrix circuit was formed on the second substrate, and a liquid crystal layer having an average thickness of 1 mm was formed between the first substrate and the second substrate. Moreover, the first polarizing plate equipped with a touch panel electrode was laminated on the first substrate on an opposite side of the liquid crystal layer, whereas the second polarizing plate and the backlight were laminated on the second substrate on an opposite side of the liquid crystal layer in this order. In this way, the liquid crystal display element was obtained. After that, the obtained liquid crystal display element was put into the storage portion of the housing.

### (3) Production of Lid Body

Next, a film made of polycarbonate and having an average thickness of 0.2 mm and a film made of polymethyl methacrylate and having an average thickness of 0.1 mm were laminated together to obtain a laminated film having an average thickness of 0.3 mm. The obtained laminated film had transparency and flexibility. Then, the obtained laminated film was cut so as to correspond to a shape of the housing. In this way, a lid body was obtained.

ITO (indium tin oxide) was supplied onto the obtained lid body using a sputtering method to obtain a touch panel electrode thereon. As described above, another touch panel electrode was, in advance, formed on a lower surface of the first polarizing plate. In this way, a capacitance-type touch panel input unit was constituted.

Next, the housing and the lid body were bonded together using an epoxy adhesive to cover the storage portion. In this way, an image display device was obtained. A maximum thickness of the obtained image display device was 5.5 mm.

### (4) Comparison of Bending Rigidity

The lid body and the first substrate, in advance, separately produced in the same manner as described above were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 40%.

### Example 2A

An image display device was obtained in the same manner as Example 1A except that the average thickness of the lid body was changed to 0.4 mm. In this regard, when the lid body was produced, used was a laminated film in which a film made of polycarbonate and having an average thickness of 0.3 mm and a film made of polymethyl methacrylate and having an average thickness of 0.1 mm were laminated together. A maximum thickness of the obtained image display device was 5.6 mm.

In this regard, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 20%.

### Example 3A

An image display device was obtained in the same manner as Example 1A except that the average thickness of the lid body was changed to 0.2 mm and the average thickness of the first substrate was changed to 50 μm. In this regard, when the lid body was produced, used was a laminated film in which a film made of polycarbonate and having an average thickness of 0.1 mm and a film made of polymethyl methacrylate and having an average thickness of 0.1 mm were laminated together. A maximum thickness of the obtained image display device was 5.4 mm.

In this regard, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 20%.

### Example 4A

An image display device was obtained in the same manner as Example 1A except that the average thickness of the lid body was changed to 0.2 mm. In this regard, when the lid body was produced, used was a laminated film in which a film made of polycarbonate and having an average thickness of 0.1 mm and a film made of polyethylene terephthalate and having an average thickness of 0.1 mm were laminated together.

In this regard, the lid body and the first substrate separately produced were cut so as to have the same shape, and bending rigidity thereof was measured. As a result, the bending rigidity of the first substrate was larger than the bending rigidity of the lid body (that is, the first substrate was hardly bent as compared with the lid body). A calculated ratio of the bending rigidity of the first substrate with respect to the bending rigidity of the lid body was 120%.

### Example 1B

### (1) Housing, Battery and Control Unit

First, a housing made of ABS resin was prepared. A size of the housing in a planar view thereof was 242 mm×186 mm.

Next, a polymer gel lithium ion battery and an electrical circuit substrate on which a CPU and a memory and the like were mounted on (control unit) were put into a storage portion of the housing.

### (2) Production of Liquid Crystal Display Element

Next, produced was a liquid crystal display element in which respective parts such as a first polarizing plate, a first substrate, a liquid crystal layer (working unit), a second substrate, a second polarizing plate and a backlight were laminated together as follows. In this regard, as each of the first polarizing plate and the second polarizing plate, used was a PVA polarizing film having an average thickness of 0.1 mm. Further, an average thickness of the backlight was 0.4 mm.

Further, as each of the first substrate and the second substrate, used was a multilayer substrate obtained by forming a resin layer onto a plate-like alkali-free glass base member. These first substrate and second substrate were produced as follows.

First, a resin varnish for forming the resin layer was prepared as follows.

1,3-bis(3-aminophenoxy)benzene was added to N,N-dimethyl acetamide and dissolved by stirring them at room temperature to obtain a solution. Thereafter, 3,3′,4,4′-benzophenonetetracarboxylic dianhydride was added to this solution and stirred, to thereby obtain a polyamic acid solution (resin varnish).

On the other hand, an ethanol solution containing a silane coupling agent including an amino group (“Z-6011” produced by Dow Corning Toray Co., Ltd.) was prepared and used as a silane coupling treatment liquid.

Next, an alkali-free glass base member having an average thickness of 0.05 mm was prepared, the silane coupling treatment liquid was applied onto one surface thereof, and then heated at 110° C. for 5 minutes.

Next, the resin varnish was applied onto the surface on which the silane coupling treatment liquid was applied. Then, the resin-varnish was heated at 170° C. for 30 minutes, to thereby obtain a resin layer constituted from thermoplastic polyimide on the alkali-free glass base member. An average thickness of the obtained resin layer was 0.01 mm and an average thickness of each of the obtained first substrate and second substrate was 0.06 mm. In this regard, a ratio of the average thickness of the resin layer with regard to the average thickness of each of the first substrate and the second substrate was 17%.

Thereafter, an active matrix circuit is formed on the second substrate, and a liquid crystal layer having an average thickness of 1 mm was formed between the first substrate and the second substrate. Moreover, the first polarizing plate equipped with a touch panel electrode was laminated on the first substrate on an opposite side of the liquid crystal layer, whereas the second polarizing plate and the backlight were laminated on the second substrate on an opposite side of the liquid crystal layer in this order. In this way, the liquid crystal display element was obtained. After that, the obtained liquid crystal display element was put into the storage portion of the housing.

The obtained first substrate and second substrate had enough flexibility and total light transmittance of 80% or more.

### (3) Production of Lid Body

Next, a film made of polycarbonate and having an average thickness of 0.2 mm and a film made of polymethyl methacrylate and having an average thickness of 0.1 mm were laminated together to obtain a laminated film having an average thickness of 0.3 mm. The obtained laminated film had transparency and flexibility. Then, the obtained laminated film was cut so as to correspond to a shape of the housing. In this way, a lid body was obtained.

ITO (indium tin oxide) was supplied onto the obtained lid body using a sputtering method to obtain a touch panel electrode thereon. As described above, another touch panel electrode was, in advance, formed on a lower surface of the first polarizing plate. In this way, a capacitance-type touch panel input unit was constituted.

The obtained lid body had enough flexibility and total light transmittance of 80% or more.

Next, the housing and the lid body were bonded together using an epoxy adhesive to cover the storage portion. In this way, an image display device was obtained. A maximum thickness of the obtained image display device was 5.5 mm.

### (4) Comparison of Bending Rigidity

The lid body and the first substrate, in advance, separately produced in the same manner as described above were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 45%.

### Example 2B

An image display device was obtained in the same manner as Example 1B except that the average thickness of the lid body was changed to 0.4 mm. In this regard, when the lid body was produced, used was a laminated film in which a film made of polycarbonate and having an average thickness of 0.3 mm and a film made of polymethyl methacrylate and having an average thickness of 0.1 mm were laminated together. A maximum thickness of the obtained image display device was 5.6 mm.

In this regard, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 25%.

### Example 3B

An image display device was obtained in the same manner as Example 1B except that the average thickness of each of the first substrate and the second substrate was changed to 0.08 mm. In this regard, as each of the first substrate and the second substrate, used was a multilayer substrate obtained by forming a resin layer having an average thickness of 0.03 mm onto a plate-like alkali-free glass base member having an average thickness of 0.05 mm. Further, a ratio of the average thickness of the resin layer with regard to the average thickness of each of the first substrate and the second substrate was 38%.

In this regard, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 60%.

### Example 4B

An image display device was obtained in the same manner as Example 1B except that the average thickness of the lid body was changed to 0.2 mm and the average thickness of each of the first substrate and the second substrate was changed to 0.08 mm. In this regard, when the lid body was produced, used was a laminated film in which a film made of polycarbonate and having an average thickness of 0.1 mm and a film made of polymethyl methacrylate and having an average thickness of 0.1 mm were laminated together. Further, as each of the first substrate and the second substrate, used was a multilayer substrate obtained by forming a resin layer having an average thickness of 0.03 mm onto a plate-like alkali-free glass base member having an average thickness of 0.05 mm. A ratio of the average thickness of the resin layer with regard to the average thickness of each of the first substrate and the second substrate was 38%. A maximum thickness of the obtained image display device was 5.4 mm.

In this regard, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 85%.

### Example 5B

An image display device was obtained in the same manner as Example 1B except that the average thickness of the lid body was changed to 0.2 mm and the average thickness of each of the first substrate and the second substrate was changed to 0.1 mm. In this regard, when the lid body was produced, used was a laminated film in which a film made of polycarbonate and having an average thickness of 0.1 mm and a film made of polyethylene terephthalate and having an average thickness of 0.1 mm were laminated together. Further, as each of the first substrate and the second substrate, used was a multilayer substrate obtained by forming a resin layer having an average thickness of 0.05 mm onto a plate-like alkali-free glass base member having an average thickness of 0.05 mm. A ratio of the average thickness of the resin layer with regard to the average thickness of each of the first substrate and the second substrate was 50%.

In this regard, the lid body and the first substrate separately produced were cut so as to have the same shape, and bending rigidity thereof was measured. As a result, the bending rigidity of the first substrate was larger than the bending rigidity of the lid body (that is, the first substrate was hardly bent as compared with the lid body). A calculated ratio of the bending rigidity of the first substrate with respect to the bending rigidity of the lid body was 110%.

### Example 6B

An image display device was obtained in the same manner as Example 1B except that as the lid body, used was a composite substrate obtained by impregnating a resin material into a glass cloth. Hereinafter, description will be made on a method for producing the composite substrate.

First, as the glass cloth, prepared was a NE glass-type glass cloth (having an average thickness of 95 μm and an average fiber size of 9 μm).

On the other hand, prepared was a resin varnish by mixing 96 parts by mass of an alicyclic epoxy resin (“E-DOA” produced by Daicel Chemical Industries, Ltd.), 4 parts by mass of silsesquioxane (“OX-SQ-H” produced by TOAGOSEI Co., Ltd.), 1 part by mass of a photocationic polymerization initiator (“SP-170” produced by ADEKA Corporation) and 25.25 parts by mass of a solvent (methyl isobutyl ketone). A refractive index of the E-DOA after being cross-linked was 1.513 and a refractive index of the OX-SQ-H after being cross-linked was 1.47.

Thereafter, the glass cloth was impregnated into the prepared resin varnish, and then subjected to a defoaming treatment. Then, the resin varnish was dried. In this way, obtained was a dried product of the resin varnish containing the glass cloth.

Next, this dried product was put between two glass plates subjected to a releasing treatment and irradiated with an ultraviolet ray having 1100 mJ/cm² using a high pressure mercury lamp. Moreover, the dried product was heated at 250° C. for 2 hours, to thereby obtain a composite substrate having an average thickness of 0.1 mm (amount of glass cloth was 57 mass %). The obtained composite substrate had transparency and flexibility.

In this regard, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 10%.

### Example 1C

### (1) Housing, Battery and Control Unit

First, a housing made of ABS resin was prepared. A size of the housing in a planar view thereof was 242 mm×186 mm.

Next, a polymer gel lithium ion battery and an electrical circuit substrate on which a CPU and a memory and the like were mounted on (control unit) were put into a storage portion of the housing.

### (2) Production of Liquid Crystal Display Element

Next, produced was a liquid crystal display element in which respective parts such as a first polarizing plate, a first substrate, a liquid crystal layer (working unit), a second substrate, a second polarizing plate and a backlight were laminated together as follows. In this regard, as each of the first polarizing plate and the second polarizing plate, used was a PVA polarizing film having an average thickness of 0.1 mm. Further, an average thickness of the backlight was 0.4 mm.

As each of the first substrate and the second substrate, used was a composite substrate obtained by impregnating a resin material into a glass cloth. These first substrate and second substrate were produced as follows.

First, as the glass cloth, prepared was a NE glass-type glass cloth (having an average thickness of 95 μm and an average fiber size of 9 μm).

On the other hand, prepared was a resin varnish by mixing 96 parts by mass of an alicyclic epoxy resin (“E-DOA” produced by Daicel Chemical Industries, Ltd.), 4 parts by mass of silsesquioxane (“OX-SQ-H” produced by TOAGOSEI Co., Ltd.), 1 part by mass of a photocationic polymerization initiator (“SP-170” produced by ADEKA Corporation) and 25.25 parts by mass of a solvent (methyl isobutyl ketone). A refractive index of the E-DOA after being cross-linked was 1.513 and a refractive index of the OX-SQ-H after being cross-linked was 1.47.

Thereafter, the glass cloth was impregnated into the prepared resin varnish, and then subjected to a defoaming treatment. Then, the resin varnish was dried. In this way, obtained was a dried product of the resin varnish containing the glass cloth.

Next, this dried product was put between two glass plates subjected to a releasing treatment and irradiated with an ultraviolet ray having 1100 mJ/cm² using a high pressure mercury lamp. Moreover, the dried product was heated at 250° C. for 2 hours, to thereby obtain a composite substrate having an average thickness of 100 μm (amount of glass cloth was 57 mass %). The obtained composite substrate had transparency and flexibility.

Thereafter, an active matrix circuit is formed on the second substrate, and a liquid crystal layer having an average thickness of 1 mm was formed between the first substrate and the second substrate. Moreover, the first polarizing plate equipped with a touch panel electrode was laminated on the first substrate on an opposite side of the liquid crystal layer, whereas the second polarizing plate and the backlight were laminated on the second substrate on an opposite side of the liquid crystal layer in this order. In this way, the liquid crystal display element was obtained. After that, the obtained liquid crystal display element was put into the storage portion of the housing.

The obtained first substrate and second substrate had enough flexibility and total light transmittance of 80% or more.

### (3) Production of Lid Body

As the lid body, used was a multilayer substrate obtained by forming a resin layer onto a plate-like alkali-free glass base member. This lid body was produced as follows.

First, a resin varnish for forming the resin layer was prepared as follows.

1,3-bis(3-aminophenoxy)benzene was added to N,N-dimethyl acetamide and dissolved by stirring them at room temperature to obtain a solution. Thereafter, 3,3′,4,4′-benzophenonetetracarboxylic dianhydride was added to this solution and stirred, to thereby obtain a polyamic acid solution (resin varnish).

On the other hand, an ethanol solution containing a silane coupling agent including an amino group (“Z-6011” produced by Dow Corning Toray Co., Ltd.) was prepared and used as a silane coupling treatment liquid.

Next, an alkali-free glass base member having an average thickness of 0.15 mm was prepared, the silane coupling treatment liquid was applied onto one surface thereof, and then heated at 110° C. for 5 minutes.

Next, the resin varnish was applied onto the surface on which the silane coupling treatment liquid was applied. Then, the resin-varnish was heated at 170° C. for 30 minutes, to thereby obtain a resin layer constituted from thermoplastic polyimide on the alkali-free glass base member. An average thickness of the obtained resin layer was 0.05 mm and an average thickness of the obtained lid body was 0.20 mm. In this regard, a ratio of the average thickness of the resin layer with regard to the average thickness of the lid body was 25%.

ITO (indium tin oxide) was supplied onto a surface of the obtained lid body using a sputtering method to obtain a touch panel electrode thereon. As described above, another touch panel electrode was, in advance, formed on a lower surface of the first polarizing plate. In this way, a capacitance-type touch panel input unit was constituted.

The obtained lid body had enough flexibility and total light transmittance of 80% or more.

Next, the housing and the lid body were bonded together using an epoxy adhesive to cover the storage portion. In this way, an image display device was obtained. A maximum thickness of the obtained image display device was 5.5 mm.

### (4) Comparison of Bending Rigidity

The lid body and the first substrate, in advance, separately produced in the same manner as described above were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 20%.

### Example 2C

An image display device was obtained in the same manner as Example 1C except that the average thickness of the lid body was changed to 0.15 mm. In this regard, as the lid body, used was a multilayer substrate obtained by forming a resin layer having an average thickness of 0.05 mm onto a plate-like alkali-free glass base member having an average thickness of 0.10 mm. A ratio of the average thickness of the resin layer with regard to the average thickness of the lid body was 33%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 35%.

### Example 3C

An image display device was obtained in the same manner as Example 1C except that the average thickness of the lid body was changed to 0.10 mm. In this regard, as the lid body, used was a multilayer substrate obtained by forming a resin layer having an average thickness of 0.05 mm onto a plate-like alkali-free glass base member having an average thickness of 0.05 mm. A ratio of the average thickness of the resin layer with regard to the average thickness of the lid body was 50%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 65%.

### Example 4C

An image display device was obtained in the same manner as Example 1C except that the average thickness of the lid body was changed to 0.07 mm. In this regard, as the lid body, used was a multilayer substrate obtained by forming a resin layer having an average thickness of 0.02 mm onto a plate-like alkali-free glass base member having an average thickness of 0.05 mm. A ratio of the average thickness of the resin layer with regard to the average thickness of the lid body was 29%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 80%.

### Example 5C

An image display device was obtained in the same manner as Example 1C except that as the lid body, used was a glass substrate formed from only an alkali-free glass base member having an average thickness of 0.075 mm.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 90%.

### Example 1D

### (1) Housing, Battery and Control Unit

First, a housing made of ABS resin was prepared. A size of the housing in a planar view thereof was 242 mm×186 mm.

Next, a polymer gel lithium ion battery and an electrical circuit substrate on which a CPU and a memory and the like were mounted on (control unit) were put into a storage portion of the housing.

### (2) Production of Liquid Crystal Display Element

Next, produced was a liquid crystal display element in which respective parts such as a first polarizing plate, a first substrate, a liquid crystal layer (working unit), a second substrate, a second polarizing plate and a backlight were laminated together as follows. In this regard, as each of the first polarizing plate and the second polarizing plate, used was a PVA polarizing film having an average thickness of 0.1 mm. Further, an average thickness of the backlight was 0.4 mm.

As each of the first substrate and the second substrate, used was a multilayer substrate obtained by forming a resin layer onto a plate-like alkali-free glass base member. These first substrate and second substrate were produced as follows.

First, a resin varnish for forming the resin layer was prepared as follows.

1,3-bis(3-aminophenoxy)benzene was added to N,N-dimethyl acetamide and dissolved by stirring them at room temperature to obtain a solution. Thereafter, 3,3′,4,4′-benzophenonetetracarboxylic dianhydride was added to this solution and stirred, to thereby obtain a polyamic acid solution (resin varnish).

On the other hand, an ethanol solution containing a silane coupling agent including an amino group (“Z-6011” produced by Dow Corning Toray Co., Ltd.) was prepared and used as a silane coupling treatment liquid.

Next, an alkali-free glass base member having an average thickness of 0.05 mm was prepared, the silane coupling treatment liquid was applied onto one surface thereof, and then heated at 110° C. for 5 minutes.

Next, the resin varnish was applied onto the surface on which the silane coupling treatment liquid was applied. Then, the resin-varnish was heated at 170° C. for 30 minutes, to thereby obtain a resin layer constituted from thermoplastic polyimide on the alkali-free glass base member. An average thickness of the obtained resin layer was 0.01 mm and an average thickness of each of the obtained first substrate and second substrate was 0.06 mm. In this regard, a ratio of the average thickness of the resin layer with regard to the average thickness of each of the first substrate and the second substrate was 17%.

Thereafter, an active matrix circuit is formed on the second substrate, and a liquid crystal layer having an average thickness of 1 mm was formed between the first substrate and the second substrate. Moreover, the first polarizing plate equipped with a touch panel electrode was laminated on the first substrate on an opposite side of the liquid crystal layer, whereas the second polarizing plate and the backlight were laminated on the second substrate on an opposite side of the liquid crystal layer in this order. In this way, the liquid crystal display element was obtained. After that, the obtained liquid crystal display element was put into the storage portion of the housing.

The obtained first substrate and second substrate had enough flexibility and total light transmittance of 80% or more.

### (3) Production of Lid Body

As the lid body, used was a multilayer substrate obtained by forming a resin layer onto a plate-like alkali-free glass base member. This lid body was produced as follows.

First, a resin varnish for forming the resin layer was prepared as follows.

1,3-bis(3-aminophenoxy)benzene was added to N,N-dimethyl acetamide and dissolved by stirring them at room temperature to obtain a solution. Thereafter, 3,3′,4,4′-benzophenonetetracarboxylic dianhydride was added to this solution and stirred, to thereby obtain a polyamic acid solution (resin varnish).

On the other hand, an ethanol solution containing a silane coupling agent including an amino group (“Z-6011” produced by Dow Corning Toray Co., Ltd.) was prepared and used as a silane coupling treatment liquid.

Next, an alkali-free glass base member having an average thickness of 0.15 mm was prepared, the silane coupling treatment liquid was applied onto one surface thereof, and then heated at 110° C. for 5 minutes.

Next, the resin varnish was applied onto the surface on which the silane coupling treatment liquid was applied. Then, the resin-varnish was heated at 170° C. for 30 minutes, to thereby obtain a resin layer constituted from thermoplastic polyimide on the alkali-free glass base member. An average thickness of the obtained resin layer was 0.05 mm and an average thickness of the obtained lid body was 0.20 mm. In this regard, a ratio of the average thickness of the resin layer with regard to the average thickness of the lid body was 25%.

ITO (indium tin oxide) was supplied onto a surface of the obtained lid body using a sputtering method to obtain a touch panel electrode thereon. As described above, another touch panel electrode was, in advance, formed on a lower surface of the first polarizing plate. In this way, a capacitance-type touch panel input unit was constituted.

The obtained lid body had enough flexibility and total light transmittance of 80% or more.

Next, the housing and the lid body were bonded together using an epoxy adhesive to cover the storage portion. In this way, an image display device was obtained. A maximum thickness of the obtained image display device was 5.5 mm.

### (4) Comparison of Bending Rigidity

The lid body and the first substrate, in advance, separately produced in the same manner as described above were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 20%.

### Example 2D

An image display device was obtained in the same manner as Example 1D except that the average thickness of the lid body was changed to 0.15 mm. In this regard, as the lid body, used was a multilayer substrate obtained by forming a resin layer having an average thickness of 0.05 mm onto a plate-like alkali-free glass base member having an average thickness of 0.10 mm. A ratio of the average thickness of the resin layer with regard to the average thickness of the lid body was 33%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 35%.

### Example 3D

An image display device was obtained in the same manner as Example 1D except that the average thickness of the lid body was changed to 0.10 mm. In this regard, as the lid body, used was a multilayer substrate obtained by forming a resin layer having an average thickness of 0.05 mm onto a plate-like alkali-free glass base member having an average thickness of 0.05 mm. A ratio of the average thickness of the resin layer with regard to the average thickness of the lid body was 50%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 65%.

### Example 4D

An image display device was obtained in the same manner as Example 1D except that the average thickness of the lid body was changed to 0.07 mm. In this regard, as the lid body, used was a multilayer substrate obtained by forming a resin layer having an average thickness of 0.02 mm onto a plate-like alkali-free glass base member having an average thickness of 0.05 mm. A ratio of the average thickness of the resin layer with regard to the average thickness of the lid body was 29%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 80%.

### Example 5D

An image display device was obtained in the same manner as Example 1D except that as the lid body, used was a glass substrate formed from only an alkali-free glass base member having an average thickness of 0.075 mm.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 90%.

### Example 6D

An image display device was obtained in the same manner as Example 1D except that the average thickness of each of the first substrate and the second substrate was changed to 0.10 mm. In this regard, as each of the first substrate and the second substrate, used was a multilayer substrate obtained by forming a resin layer having an average thickness of 0.05 mm onto a plate-like alkali-free glass base member having an average thickness of 0.05 mm. Further, a ratio of the average thickness of the resin layer with regard to the average thickness of each of the first substrate and the second substrate was 50%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 50%.

### Example 7D

An image display device was obtained in the same manner as Example 1D except that the average thickness of each of the first substrate and the second substrate was changed was 0.15 mm. In this regard, as each of the first substrate and the second substrate, used was a multilayer substrate obtained by forming a resin layer having an average thickness of 0.05 mm onto a plate-like alkali-free glass base member having an average thickness of 0.10 mm. Further, a ratio of the average thickness of the resin layer with regard to the average thickness of each of the first substrate and the second substrate was 33%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 75%.

### Example 8D

An image display device was obtained in the same manner as Example 1D except that the average thickness of each of the first substrate and the second substrate was changed was 0.17 mm. In this regard, as each of the first substrate and the second substrate, used was a multilayer substrate obtained by forming a resin layer having an average thickness of 0.02 mm onto a plate-like alkali-free glass base member having an average thickness of 0.15 mm. Further, a ratio of the average thickness of the resin layer with regard to the average thickness of each of the first substrate and the second substrate was 12%.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 95%.

### Example 9D

An image display device was obtained in the same manner as Example 1D except that as each of the first substrate and the second substrate, used was a glass substrate formed from only an alkali-free glass base member having an average thickness of 0.05 mm.

Further, the lid body and the first substrate separately produced were cut so as to have the same shape, and bending rigidity thereof was measured. As a result, the bending rigidity of the first substrate was smaller than the bending rigidity of the lid body (that is, the first substrate was easily bent as compared with the lid body). A calculated ratio of the bending rigidity of the first substrate with respect to the bending rigidity of the lid body was 30%.

### Comparative Example 1

An image display device was obtained in the same manner as Example 1A except that as each of the first substrate and the second substrate, used was an alkali-free glass substrate having an average thickness of 0.4 mm, and as the lid body, used was an alkali-free glass substrate having an average thickness of 0.8 mm. In this regard, each of the above mentioned alkali-free glass substrates had transparency, but could not be easily bent with hand and thus did not have flexibility. Further, a maximum thickness of the obtained image display device was 6.2 mm.

### Comparative Example 2

An image display device was obtained in the same manner as Example 1C or Example 1D except that as the lid body, used was a laminated substrate in which a resin layer having an average thickness of 0.005 mm was formed on a glass base member having an average thickness of 0.01 mm. However, deformation of the lid body became too large, and thus it was impossible to obtain an image display device capable of displaying a fine image.

### Comparative Example 3

An image display device was obtained in the same manner as Example 1B or Example 1D except that as each of the first substrate and the second substrate, used was a laminated substrate in which a resin layer having an average thickness of 0.005 mm was formed on a glass base member having an average thickness of 0.01 mm. However, deformation of each of the first substrate and the second substrate was large, and thus warpage of the display element became too large, which made it impossible to obtain an image display device capable of displaying a fine image.

### 2. Evaluation of Image Display Device

### 2.1 Weight Measurement of Image Display Device

Weight of the image display device obtained in each of Examples and Comparative Examples was measured. As a result, the weight of the image display device obtained in each of Examples and Comparative Examples 2 and 3 was within the range of 480 to 520 g, whereas the weight of the image display device obtained in Comparative Example 1 was 700 g.

### 2.2 Drop Test of Image Display Device

The image display device obtained in each of Examples and Comparative Example 1 was subjected to a gravity-drop test with displaying an image. The gravity-drop test was carried out according to a gravity-drop test method defined in JIS C 60068-2-32. A drop height was set to 1000 mm and a drop floor surface was set to a flat concrete surface. Further, a drop posture of the image display device was kept so that the display surface thereof became parallel to a vertical direction and one corner thereof would make contact with ground earliest. The drop was carried out two times by selecting the one corner and the other corner.

As a result of the gravity-drop test, in the image display device obtained in each of Examples, recesses were formed on an exterior thereof (corners of housing), but a normal image display could be kept. On the other hand, in the image display device obtained in Comparative Example 1, the alkali-free glass substrates used for the lid body and the display element were cracked, and thus the image display device became a state not capable of displaying a normal image.

In this regard, the image display device obtained in each of Examples was subjected to the additional gravity-drop test eight times. As a result, the image display device obtained in each of Examples 1A to 3A could display the normal image even after the drop tests were carried out ten times in total, but the image display device obtained in Example 4A caused display unevenness after the drop tests were carried out eight times in total.

Further, the image display device obtained in each of Examples 1B to 3B and 6B could display the normal image even after the drop tests were carried out ten times in total, but the image display device obtained in Example 4B caused display unevenness after the drop tests were carried out eight times in total and the image display device obtained in Example 5B caused display unevenness after the drop tests were carried out four times in total.

Further, the image display device obtained in each of Examples 1C to 4C could display the normal image even after the drop tests were carried out ten times in total, but the image display device obtained in Example 5C caused display unevenness after the drop tests were carried out eight times in total.

Furthermore, the image display device obtained in each of Examples 1D to 4D, 6D and 7D could display the normal image even after the drop tests were carried out ten times in total, but the image display device obtained in Example 8D caused display unevenness after the drop tests were carried out six times in total and the image display device obtained in each of Examples 5D and 9D caused display unevenness after the drop tests were carried out three times in total.

### INDUSTRIAL APPLICABILITY

According to the present invention, each of an opposite substrate and an element substrate of a display element, which are provided on a side of a display surface, contains a resin material or a plate-like glass base member. In the case where the opposite substrate contains the glass base member, an average thickness of the opposite substrate is in the range of 0.02 to 0.2 mm, and in the case where the element substrate contains the glass base member, an average thickness of the element substrate is in the range of 0.02 to 0.2 mm. This makes it possible to provide an image display device having light weight and excellent impact resistance. Therefore, the present invention has industrial applicability.

What is claimed is:

1. An image display device comprising:
a plate-like base substrate;
a transparent opposite substrate provided opposite to the base substrate and having flexibility; and
a display element provided between the base substrate and the opposite substrate, the display element including a transparent element substrate having flexibility and a working unit provided on a side of one surface of the element substrate,
wherein each of the opposite substrate and the element substrate contains a resin material or a plate-like glass base member, and
wherein in the case where the opposite substrate contains the glass base member, an average thickness of the opposite substrate is in the range of 0.02 to 0.2 mm, and in the case where the element substrate contains the glass base member, an average thickness of the element substrate is in the range of 0.02 to 0.2 mm.

2. The image display device as claimed in claim 1, wherein bending rigidity of the element substrate is lower than that of the opposite substrate.

3. The image display device as claimed in claim 1, wherein in the case where the opposite substrate contains the resin material, the opposite substrate is formed by impregnating the resin material into a glass fabric, and in the case where the element substrate contains the resin material, the element substrate is formed by impregnating the resin material into a glass fabric.

4. The image display device as claimed in claim 1, wherein the glass base member is formed of alkali-free glass.

5. The image display device as claimed in claim 1, wherein in the case where the opposite substrate contains the glass base member, the opposite substrate contains the glass base member and a resin layer laminated on the glass base member, and in the case where the element substrate contains the glass base member, the element substrate contains the glass base member and a resin layer laminated on the glass base member.

6. The image display device as claimed in claim 1, wherein the display element further includes an opposite element substrate provided opposite to the element substrate via the working unit.

7. The image display device as claimed in claim 1, wherein the working unit is capable of electrooptically displaying an image.

8. The image display device as claimed in claim 1, comprising a capacitance-type touch panel input unit.

9. The image display device as claimed in claim 1, wherein the opposite substrate contains the resin material.

10. The image display device as claimed in claim 9, wherein an average thickness of the opposite substrate is in the range of 0.02 to 0.8 mm.

11. The image display device as claimed in claim 9, wherein the resin material contained in the opposite substrate contains a polycarbonate-based resin or a (meth)acrylate-based resin as a major component thereof.

12. The image display device as claimed in claim 1, wherein the opposite substrate contains the glass base member.

13. The image display device as claimed in claim 1, wherein the element substrate contains the resin material.

14. The image display device as claimed in claim 13, wherein an average thickness of the element substrate is in the range of 0.01 to 0.3 mm.

15. The image display device as claimed in claim 13, wherein the resin material contained in the element substrate contains a cross-linked product of a cross-linkable resin as a major component thereof.

16. The image display device as claimed in claim 15, wherein the cross-linkable resin is an alicyclic epoxy-based resin or an alicyclic acryl-based resin.

17. The image display device as claimed in claim 1, wherein the element substrate contains the glass base member.
